(19) United States
(12) Patent Application Publication
(10) Pub. No.: US 2008/0283929 A1
(43) Pub. Date: Nov. 20, 2008

(54) SEMICONDUCTOR DEVICE AND MANUFACTURING METHOD OF THE SAME

(75) Inventor: Toshihide Nabatame, Tokyo (JP)

Correspondence Address: MILES & STOCKBRIDGE PC, 1751 PINNACLE DRIVE, SUITE 500, MCLEAN, VA, 22102-3833, US

(73) Assignee: Renesas Technology Corp.

(21) Appl. No.: 12/118,730

(22) Filed: May 11, 2008

(30) Foreign Application Priority Data
May 15, 2007 (JP) JP 2007-128691

(51) Int. Cl. H01L 27/092; H01L 21/28

(52) U.S. Cl. 257/369; 438/591; 257/E21.194; 257/E21.202; 257/E27.062

(57) ABSTRACT

In a p channel MOS transistor and an n channel MOS transistor each having a gate electrode made of metal on a gate insulating film made of oxide whose relative dielectric constant is higher than that of silicon oxide, threshold voltage thereof is reduced. A gate insulating film of a p channel MOS transistor and an n channel MOS transistor is made of hafnium oxide, a gate electrode of the p channel MOS transistor is made of ruthenium, and a gate electrode of the n channel MOS transistor is made of alloy containing ruthenium as a base material and hafnium.

### CROSS-REFERENCE TO RELATED APPLICATION

The present application claims priority from Japanese Patent Application No. JP 2007-128691 filed on May 15, 2007, the content of which is hereby incorporated by reference into this application.

### TECHNICAL FIELD OF THE INVENTION

The present invention relates to a semiconductor device and a manufacturing method thereof. More particularly, it relates to a technology effectively applied to a semiconductor device including a MOS transistor having a gate insulating film made of oxide whose relative dielectric constant is higher than that of silicon oxide (SiO₂) and a gate electrode made of metal.

### BACKGROUND OF THE INVENTION

In a p channel MOS transistor and an n channel MOS transistor constituting a CMOS (Complementary Metal Oxide Semiconductor) circuit, a silicon oxide film is used as a material of a gate insulating film, and a polysilicon film or a stacked film (polycide film) obtained by stacking a metal silicide film such as a tungsten silicide film or a cobalt silicide film on a polysilicon film is used as a material of a gate electrode formed on the gate insulating film.

In recent years, with the trend of scaling down the size of MOS transistors constituting a semiconductor integrated circuit, the thickness of a gate insulating film formed of a silicon oxide film has been rapidly reduced. As the thickness of a gate insulating film gets smaller, when voltage is applied to a gate electrode to turn ON a MOS transistor, the influence of depletion caused in the gate electrode (polysilicon film) near the interface of the gate insulating film becomes more and more conspicuous, and the thickness of the gate insulating film increases in appearance. As a result, it has become difficult to secure an ON current, and the reduction in operation speed of a transistor has become conspicuous.

In addition, when the thickness of a gate insulating film is reduced, the leakage current increases because electrons pass through the gate insulating film due to the quantum effect called direct tunneling. Further, in a p channel MOS transistor, boron in the gate electrode formed of a polysilicon film diffuses in a substrate through the gate insulating film and the impurity concentration of the channel region is increased, and thus, the threshold voltage fluctuates.

Therefore, studies on the replacement of a gate insulating film material to an insulating material whose relative dielectric constant is higher than that of silicon oxide (high dielectric material or high-k material) and the replacement of a gate electrode material from polysilicon (or polycide) to metal have been proceeding.

This is because, when a high dielectric film is used to form a gate insulating film, even if the capacitance of an equivalent silicon oxide thickness is the same, the actual physical thickness can be increased by a factor of “relative dielectric constant of high dielectric film/relative dielectric constant of silicon oxide film”, and as a result, the leakage current can be reduced. As the material of the high dielectric films, various metal oxides such as hafnium oxide and zirconium oxide have been studied.

In addition, by using a metal material containing no polysilicon to form a gate electrode, the above-mentioned problems of the reduction of the ON current due to the influence of the depletion and the boron leakage from the gate electrode to the substrate can be prevented.

Incidentally, low power consumption design is important for the CMOS circuit. For its achievement, it is required to reduce the threshold voltage of each of a p channel MOS transistor and an n channel MOS transistor. Therefore, even when a high dielectric material such as hafnium oxide is used to form a gate insulating film and a gate electrode material is replaced with a metal material, it is necessary that a gate electrode material having the work function suitable for each of a p channel MOS transistor and an n channel MOS transistor is selected so as to suppress the increase in the threshold voltage. For example, the work function of a gate electrode material of a p channel MOS transistor is about 5.0 eV, and the work function of a gate electrode material of an n channel MOS transistor is about 4.1 eV.

In addition, the inventors of the present invention have made a prior-art search based on the invented results, in the light of an aspect of using a high dielectric material and metal for a gate insulating film and a gate electrode of a MOS transistor and in the light of an aspect of using the same metal material for gate electrodes of an n channel MOS transistor and a p channel MOS transistor. As a result, Japanese Patent Application Laid-Open Publication No. 2004-165555 (Patent Document 1), Japanese Patent Application Laid-Open Publication No. 2004-165346 (Patent Document 2), Japanese Patent Application Laid-Open Publication No. 2006-080133 (Patent Document 3) have been extracted.

Japanese Patent Application Laid-Open Publication No. 2004-165555 (Patent Document 1) discloses a CMOS circuit in which a gate electrode of an n channel MOS transistor is made of any one of titanium, aluminum, tantalum, molybdenum, hafnium and niobium, and a gate electrode of a p channel MOS transistor is made of any one of tantalum nitride, ruthenium oxide, iridium, platinum, tungsten nitride and molybdenum nitride.

Further, Japanese Patent Application Laid-Open Publication No. 2004-165346 (Patent Document 2) discloses a CMOS circuit in which a gate electrode of an n channel MOS transistor is made of aluminum, and a gate electrode of a p channel MOS transistor is made of composite metal obtained by introducing metal having a work function higher than that of aluminum (for example, cobalt, nickel, ruthenium, iridium and platinum) to aluminum.

Further, Japanese Patent Application Laid-Open Publication No. 2006-080133 (Patent Document 3) discloses a CMOS circuit in which gate insulating films of an n channel MOS transistor and a p channel MOS transistor are made of a hafnium oxide film, a gate electrode of an n channel MOS transistor is made of a nickel silicide film, and a gate electrode of a p channel MOS transistor is made of a platinum film.

### SUMMARY OF THE INVENTION

As described above, a gate electrode having the work function suitable for each of a p channel MOS transistor and an n channel MOS transistor has to be formed in order to reduce the threshold voltage of each of the p channel MOS transistor and the n channel MOS transistor constituting a CMOS circuit.

In addition, when different metal materials are used to form gate electrodes of an n channel MOS transistor and a p channel MOS transistor, such a problem occurs that a transistor manufacturing process is complicated and the number of steps is far increased.

An object of the present invention is to provide the technology capable of reducing threshold voltage of each of an n channel MOS transistor and a p channel MOS transistor in which a gate electrode made of metal is formed on a gate insulating film made of oxide whose relative dielectric constant is higher than that of silicon oxide.

The above and other objects and novel characteristics of the present invention will be apparent from the description of this specification and the accompanying drawings.

The typical ones of the inventions disclosed in this application will be briefly described as follows.

In an embodiment of the present invention, gate insulating films of a p channel MOS transistor and an n channel MOS transistor are made of hafnium oxide, a gate electrode of a p channel MOS transistor is made of ruthenium, and a gate electrode of an n channel MOS transistor is made of alloy containing ruthenium as a base material and hafnium.

The effects obtained by typical aspects of the present invention will be briefly described below.

According to the embodiment, even when the same metal material is used for gate electrodes of a p channel MOS transistor and an n channel MOS transistor, a work function of the gate electrode of the n channel MOS transistor can be made lower than that of the gate electrode of the p channel MOS transistor. Therefore, the threshold voltage of each of an n channel MOS transistor and a p channel MOS transistor can be reduced.

### BRIEF DESCRIPTIONS OF THE DRAWINGS

FIG. 1 is a cross-sectional view showing a principal part of a semiconductor device in a manufacturing process according to the first embodiment of the present invention;

FIG. 2 is a cross-sectional view showing a principal part of the semiconductor device in the manufacturing process continued from FIG. 1;

FIG. 3 is a cross-sectional view showing a principal part of the semiconductor device in the manufacturing process continued from FIG. 2;

FIG. 4 is a cross-sectional view showing a principal part of the semiconductor device in the manufacturing process continued from FIG. 3;

FIG. 5 is a cross-sectional view showing a principal part of the semiconductor device in the manufacturing process continued from FIG. 4;

FIG. 6 is a cross-sectional view showing a principal part of the semiconductor device in the manufacturing process continued from FIG. 5;

FIG. 7 is a cross-sectional view showing a principal part of the semiconductor device in the manufacturing process continued from FIG. 6;

FIG. 8 is a cross-sectional view showing a principal part of the semiconductor device in the manufacturing process continued from FIG. 7;

FIG. 9 is a cross-sectional view showing a principal part of the semiconductor device in the manufacturing process continued from FIG. 8;

FIG. 10 is a cross-sectional view showing a principal part of the semiconductor device in the manufacturing process continued from FIG. 9;

FIG. 11 is a graph showing the change of the effective work function relative to the Hf content in the case where a gate electrode and a gate insulating film are made of Hf—Ru and HfO₂, respectively;

FIG. 12A is a schematic diagram for describing an atomic arrangement of a gate electrode and a gate insulating film in the pMOS formation region;

FIG. 12B is a schematic diagram for describing an atomic arrangement of a gate electrode and a gate insulating film in the nMOS formation region;

FIG. 13 is a cross-sectional view showing a principal part of a semiconductor device in a manufacturing process according to the second embodiment of the present invention;

FIG. 14 is a cross-sectional view showing a principal part of the semiconductor device in the manufacturing process continued from FIG. 13;

FIG. 15 is a cross-sectional view showing a principal part of the semiconductor device in the manufacturing process continued from FIG. 14;

FIG. 16 is a graph showing the change of the effective work function relative to the Ru thickness in the case where a gate electrode and a gate insulating film are made of Hf/Ru stacked structure and HfO₂, respectively;

FIG. 17 is a graph showing the change of the effective work function relative to the Hf content in the case where a gate electrode and a gate insulating film are made of Hf—Ru and Al₂O₃, respectively;

FIG. 18 is a graph showing the change of the effective work function relative to the Ru thickness in the case where a gate electrode and a gate insulating film are made of Hf/Ru stacked structure and Al₂O₃, respectively;

FIG. 19 is a drawing in which the work functions of various elements are plotted;

FIG. 20 is a cross-sectional view showing a principal part of a semiconductor device in a manufacturing process according to the fifth embodiment of the present invention;

FIG. 21 is a cross-sectional view showing a principal part of the semiconductor device in the manufacturing process continued from FIG. 20;

FIG. 22 is a cross-sectional view showing a principal part of a semiconductor device in a manufacturing process according to the sixth embodiment of the present invention;

FIG. 23 is a cross-sectional view showing a principal part of the semiconductor device in the manufacturing process continued from FIG. 22;

FIG. 24 is a cross-sectional view showing a principal part of the semiconductor device in the manufacturing process continued from FIG. 23;

FIG. 25 is a cross-sectional view showing a principal part of the semiconductor device in the manufacturing process continued from FIG. 24;

FIG. 26 is a cross-sectional view showing a principal part of the semiconductor device in the manufacturing process continued from FIG. 25; and

FIG. 27 is a cross-sectional view showing a principal part of the semiconductor device in the manufacturing process continued from FIG. 26.

### DESCRIPTIONS OF THE PREFERRED EMBODIMENTS

Hereinafter, embodiments of the present invention will be described in detail with reference to the accompanying drawings. Note that components having the same function are denoted by the same reference numbers throughout the drawings for describing the embodiment, and the repetitive description thereof will be omitted.

### First Embodiment

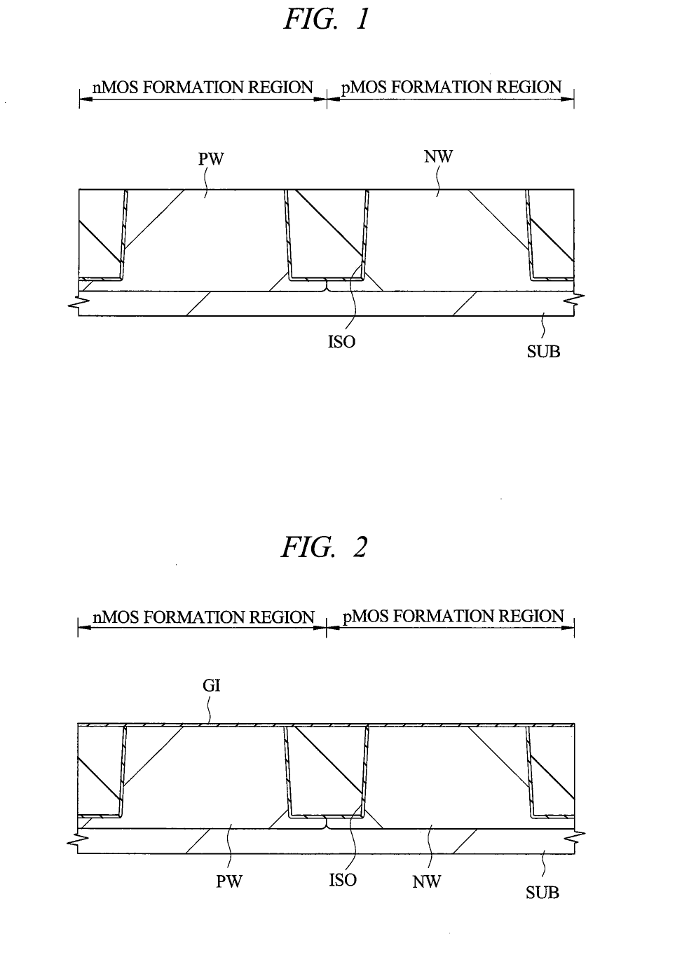

A manufacturing method of a CMOS (Complementary Metal Oxide Semiconductor) constituted of an n channel MOS transistor and a p channel MOS transistor according to the first embodiment will be described with reference to FIG. 1 to FIG. 10.

First, as shown in FIG. 1, element isolation trenches ISO are formed using a well-known STI (Shallow Trench Isolation) technology in a main surface (element formation surface) of a semiconductor substrate (hereinafter, referred to as substrate) SUB made of p type single crystal silicon.

Subsequently, boron is ion-implanted into an n channel MOS transistor formation region (hereinafter, referred to as nMOS formation region, on the left side of the drawing) of the substrate SUB, and phosphorus is ion-implanted into a p channel MOS transistor formation region (hereinafter, referred to as pMOS formation region, on the right side of the drawing). Then, impurity ions for adjusting the threshold voltage of the MOS transistors are implanted into the nMOS formation region and the pMOS formation region of the substrate SUB. Further, the substrate SUB is subjected to heat treatment to diffuse the impurity in the substrate SUB, thereby forming a p well PW and an n well NW in the main surface (element formation surface) of the substrate SUB.

Subsequently, as shown in FIG. 2, an interface layer made of silicon oxide (SiO₂) is formed on the surface of each of the p well PW of the nMOS formation region and the n well NW of the pMOS formation region (main surface of substrate SUB), and then a gate insulating film GI made of hafnium oxide (HfO₂) is formed thereon.

The silicon oxide film is formed by, for example, removing a natural oxide film with diluted hydrofluoric acid solution and then performing high-temperature heat treatment oxidation at 950° C. or higher. Also, the hafnium oxide film is formed by, for example, depositing a film by the atomic layer deposition (ALD) using an oxygen (O) material of H₂O gas and a hafnium (Hf) material of TDMAH (Tetrakis-Dimethylamido-Hafnium: Hf(NMe₂)₄) and then performing the post deposition annealing (PDA) for reducing the defects in the film.

This hafnium oxide is hafnium-based oxide whose relative dielectric constant is higher than that of silicon oxide (SiO₂). If the relative dielectric constant of the gate insulating film GI made of the hafnium oxide is 16, when the film thickness is, for example, 3.2 nm, the equivalent oxide thickness (EOT) is, for example, 0.8 nm. In this case, the leakage current when the MOS transistor is in an ON state can be reduced in comparison to a MOS transistor having a gate insulating film formed of a silicon oxide film with the same thickness.

Further, the hafnium oxide is an ion conductor, and stability in bonding is weaker than covalent silicon oxide. As the gate insulating film GI, hafnium-based oxide such as Hf—Si—O, Hf—Si—O—N, Hf—Al—O, Hf—Al—O—N, Hf—Ta—O, Hf—Ti—O, Hf—La—O, Hf—Y—O, Hf—Ta—Si—O, Hf—Ti—Si—O, Hf—La—Si—O or Hf—Y—Si—O can be applied other than hafnium oxide (Hf—O). Note that, in the present invention, a material containing oxygen (O) and hafnium (Hf) and having relative dielectric constant higher than that of silicon oxide (SiO₂) is referred to as “hafnium-based oxide”.

The hafnium-based oxide is also an ion conductor, and stability in bonding is weaker than covalent silicon oxide. Also, in the formation thereof, the ALD method is used, and materials for the respective oxides are used in addition to the O material of H₂O gas and the Hf material of TDMAH (Hf(NMe₂)₄). For example, TDMAS (Trisdimethlaminosilane: HSi(NMe₂)₃) is used as an Si (silicon) material. Also, TMA (Trimethylaluminum: AlMe₃) is used as an Al (aluminum) material. Also, TAIDEAT (tertiaryamylimidotris(dimethlamido)tantalum: EtMe₂CNTa(NMe₂)₃) is used as a Ta (tantalum) material. Also, TDMAT (Tetrakisdimethylaminotitanium: Ti(NMe₂)₃) is used as a Ti (titanium) material. Also, Trisethylcyclopentadienylyttrium: Y(EtCp)₃ is used as a Y (yttrium) material. Also, Trisethylcyclopentadienyllanthanum: La(EtCp)₃ is used as an La (lanthanum) material. Further, the nitridation of Hf—Si—O—N and Hf—Al—O—N is fabricated by the nitridation by the plasma nitrogen and the nitridation by the heat treatment using ammonia gas after depositing an Hf—Si—O film or an Hf—Al—C film by the ALD.

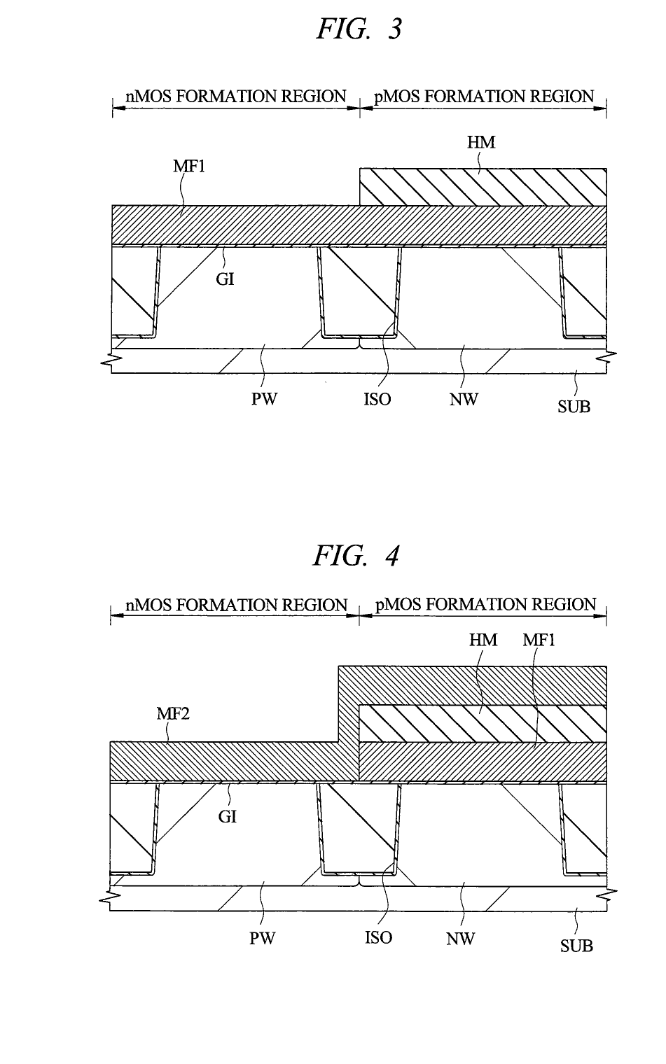

Subsequently, as shown in FIG. 3, a metal film MF1 made of ruthenium is deposited (formed) on the gate insulating film GI by sputtering, and a silicon nitride film is deposited on the metal film MF1 by chemical vapor deposition (CVD). Thereafter, the silicon nitride film is patterned by the dry etching using a photoresist film (not shown) as a mask, thereby forming a hard mask HM in the pMOS formation region. In the first embodiment, the thickness of the metal film MF1 made of ruthenium is, for example, 20 nm.

Subsequently, as shown in FIG. 4, the metal film MF1 of the nMOS formation region is removed by etching to expose the gate insulating film GI of the nMOS formation region. Thereafter, a metal film MF2 made of alloy containing ruthenium as a base material and hafnium (Hf—Ru) is deposited (formed) on the gate insulating film GI by sputtering. In the first embodiment, for example, the metal film MF2 containing ruthenium as a base material and hafnium of 10 atom % and having the film thickness of 20 nm is formed.

Although described in detail later, in the first embodiment, the gate electrode of an n channel MOS transistor is made of alloy (Hf—Ru) containing hafnium, which is more oxidation stable than hafnium oxide (HfO₂).

Subsequently, a silicon nitride film is deposited on the metal film MF2 by CVD, and the silicon nitride film is patterned by the dry etching using a photoresist film (not shown) as a mask, thereby forming a hard mask (not shown) in the nMOS formation region. Thereafter, the metal film MF2 of the pMOS formation region is removed by etching.

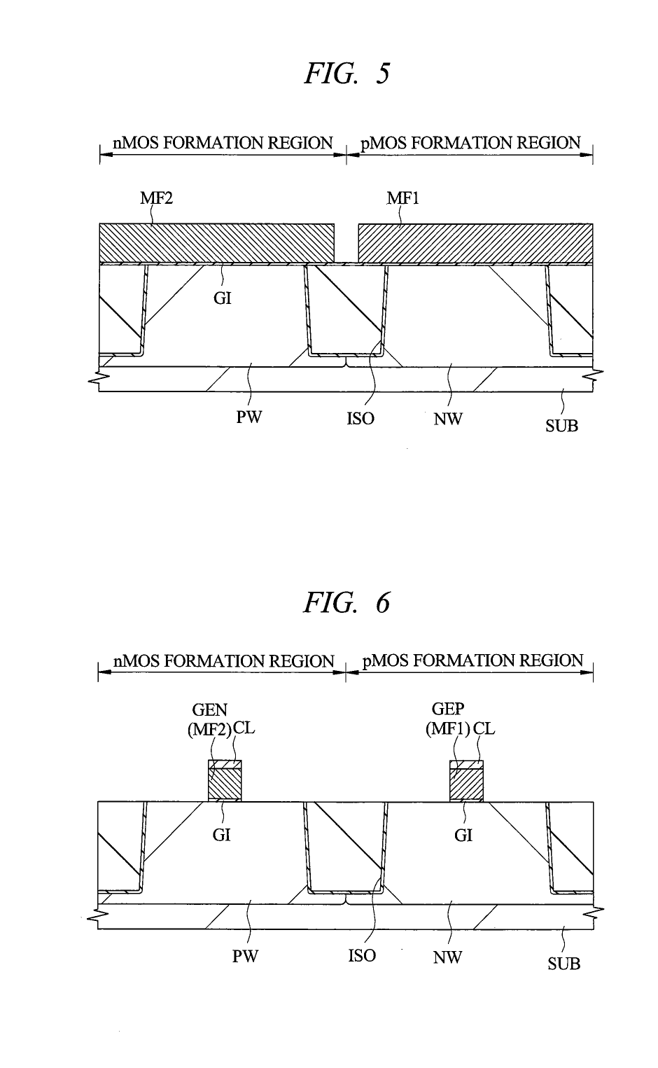

Then, as shown in FIG. 5, the hard mask HM of the pMOS formation region and the hard mask of the nMOS formation region are removed.

Then, as shown in FIG. 6, a cap layer CL made of tantalum nitride (barrier metal) is deposited (formed) on the metal film MF1 of the pMOS formation region and the metal film MF2 of the nMOS formation region. Thereafter, the cap layer CL and the metal films MF1 and MF2 are patterned by the dry etching using a photoresist film (not shown) as a mask. By this means, a gate electrode GEP formed of the metal film MF1 and a gate electrode GEN formed of the metal film MF2 are formed on the gate insulating film GI of the n well NW and the gate insulating film GI of the p well PW, respectively.

The cap layer CL is made of barrier metal provided in order to prevent oxygen from reaching the metal films MF1 and MF2 even if the substrate SUB is exposed to the ambient air containing oxygen, and tantalum nitride is used in the first embodiment. Note that the cap layer CL is not always necessary for the pMOS formation region. Ruthenium is used as the metal film MF1 in the present embodiment, and an advantage can be gained in the case where the cap layer CL is not formed because ruthenium oxide (RuO₂) having high work function of 5.0 eV can be obtained by oxygen during the process and ruthenium oxide can be formed more stably.

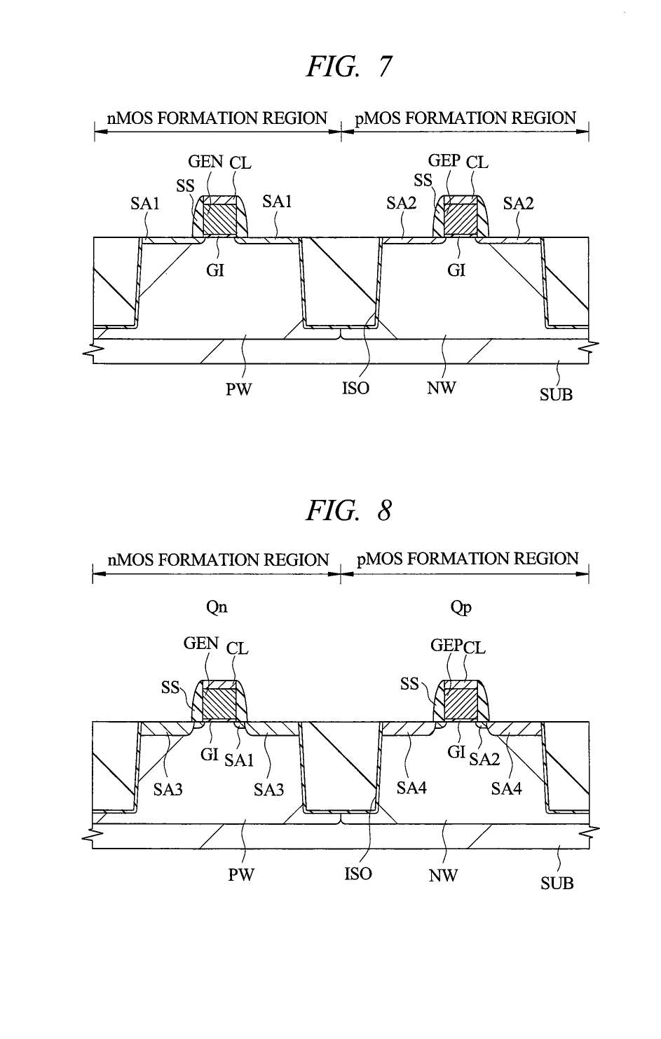

Subsequently, as shown in FIG. 7, phosphorus or arsenic is ion-implanted into the p well PW to form n⁻ semiconductor regions SA1, and boron is ion-implanted into the n well NW to form p⁻ semiconductor regions SA2. Thereafter, sidewall spacers SS are formed on the sidewalls of the gate electrode GEP and the gate electrode GEN. The n⁻ semiconductor regions SA1 are formed to form an LDD (Lightly Doped Drain) structure of the n channel MOS transistor, and the p⁻ semiconductor regions SA2 are formed to form an LDD structure of the p channel MOS transistor. The sidewall spacers SS are formed by depositing a silicon oxide film by CVD on the substrate SUB, and then anisotropically etching the silicon oxide film.

Subsequently, as shown in FIG. 8, after phosphorus or arsenic is ion-implanted into the p well PW and boron is ion-implanted into the well NW, the substrate SUB is subjected to the heat treatment to diffuse these impurities. By this means, n⁺ semiconductor regions (source, drain) SA3 are formed in the p well PW and p⁺ semiconductor regions (source, drain) SA4 are formed in the n well NW.

Then, the substrate SUB is annealed so that oxygen is lost from the gate insulating film GI made of oxide in the nMOS formation region. In other words, the substrate SUB is annealed so that oxygen of hafnium oxide forming the gate insulating film GI of the nMOS formation region and hafnium forming the gate electrode GEN are bonded. In the present embodiment, the substrate SUB is rapidly annealed at 1000° C. for about 5 seconds.

The annealing temperature by which the oxygen of the gate insulating film GI of the nMOS formation region is lost in comparison to that before the annealing, in other words, the annealing temperature for bonding oxygen of hafnium oxide forming the gate insulating film GI and hafnium forming the gate electrode GEN may be 400° C. or higher. The annealing process for losing the oxygen from oxide (hereinafter, referred to as “oxygen-deficient annealing”) may be performed before the process of forming the sidewall spacers SS on the sidewalls of the gate electrode GE, and may be performed before the process of forming the n⁻ semiconductor regions SA1, the p⁻ semiconductor regions SA2, the n⁺ semiconductor regions SA3 and the p⁺ semiconductor regions SA4. In addition, since the oxygen deficiency occurs if the temperature reaches 400° C. or higher, the oxygen-deficient annealing can be done with the impurity diffusion process for forming the n⁺ type semiconductor regions (source, drain) SA3 in the p well PW and the p⁺ semiconductor regions (source, drain) SA4 in the n well NW.

Through the process described above, an n channel MOS transistor Qn and a p channel MOS transistor Qp are completed.

When the effective work function of the gate electrodes GEP and GEN is measured, the effective work function of the gate electrode GEN is lower than that of the gate electrode GEP. In the first embodiment, ruthenium is used as a base material and 10 atom % of hafnium is added in the formation of the gate electrode GEN. In this case, the effective work function of the gate electrode GEN is 4.5 eV, and the effective work function of the gate electrode GEP made of ruthenium is 5.0 eV.

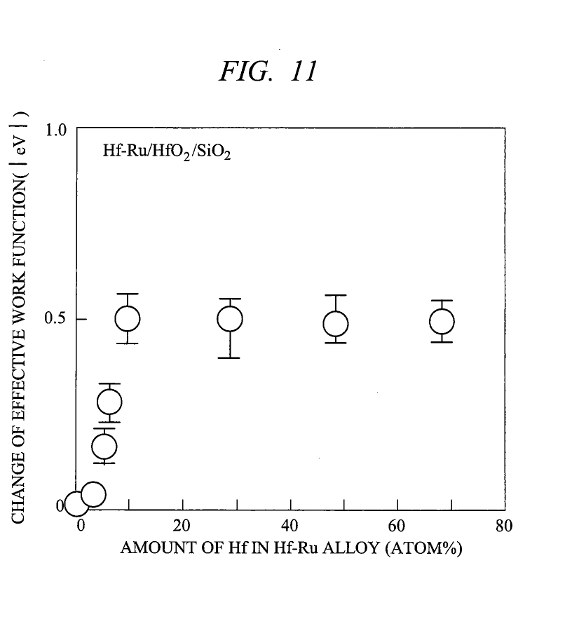

FIG. 11 shows the change of the effective work function relative to the hafnium (Hf) content of the n channel MOS transistor Qn with respect to the p channel MOS transistor Qp in the present embodiment. As shown in FIG. 11, by increasing the Hf content, the difference in the effective work function between the p channel MOS transistor Qp and the n channel MOS transistor Qn increases, and the difference reaches 0.5 eV when the Hf content is 10 atom %. In addition, the difference in the effective work function saturates when the Hf content is increased to more than 10 atom %.

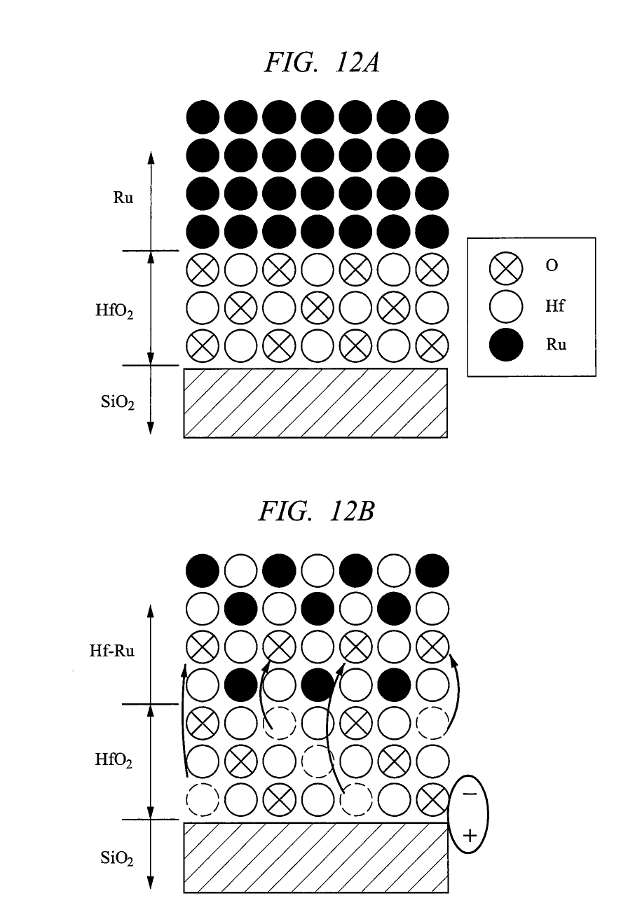

From the description above, it can be said that the alloy containing ruthenium as a base material and hafnium for forming the gate electrode GEN shifts the work function as a gate electrode material relative to ruthenium for forming the gate electrode GEP. The reason why the work function of the gate electrode GEN is lower than that of the gate electrode GEP will be described below with reference to FIG. 12.

FIG. 12A and FIG. 12B are schematic diagrams for describing the atomic arrangement of the gate electrodes GEP and GEN and the gate insulating film GI after the oxygen-deficient annealing, and FIG. 12A shows the pMOS formation region and FIG. 12B shows the nMOS formation region. In view of the case where a silicon oxide (SiO₂) layer is formed at the interface between the substrate SUB and the gate insulating film GI by the oxygen-deficient annealing, an SiO₂ layer is shown as the bottom layer in FIG. 12. A hafnium oxide (HfO₂) layer forming the gate insulating film GI is deposited on this SiO₂ layer. Further, a ruthenium (Ru) layer forming the gate electrode GEP is deposited on the HfO₂ layer in FIG. 12A, and an alloy (Hf—Ru) layer containing ruthenium as a base material and hafnium (Hf) forming the gate electrode GEN is deposited on the HfO₂ layer in FIG. 12B.

First, the HfO₂ layer of FIG. 12A is densified by performing the oxygen-deficient annealing. On the other hand, as shown in FIG. 12B, hafnium is bonded to oxygen released from the HfO₂ layer in the Hf—Ru layer. This is because the gate electrode GEN is made of alloy (Hf—Ru) containing ruthenium as a base material and metal (hafnium in the first embodiment) which is oxidation stable than the HfO₂ layer. Therefore, hafnium contained in the gate electrode GEN is bonded to oxygen.

The oxidation stable metal mentioned here is the metal which is easily oxidized and is more stabilized when bonded to oxygen. Thus, the metal which is more oxidation stable than an HfO₂ layer is the layer which causes oxygen to release from the HfO₂ layer and is bonded to the oxygen. In addition, the element having lower work function is the metal oxidized more easily. It is well-known that the work function of metal is generally proportional to the electronegativity. In addition, the work function of metal and the standard energy of formation of the oxide thereof have correlations, and the metal with lower work function has larger standard energy of formation of the oxide, and the oxide is more stable than metal form.

Subsequently, since oxygen has been taken out, the HfO₂ layer is deficient in oxygen. Then, electrons are accumulated in the HfO₂ layer due to the oxygen deficiency, and dipole is generated at the interface of the HfO₂ layer and the SiO₂ layer.

It is thought that the effective work function of the gate electrode GEN after the oxygen-deficient annealing becomes lower than the effective work function of the gate electrode GEP with such a mechanism. In comparison to the gate electrode GEP of the p channel MOS transistor Qp made of ruthenium (Ru), in the gate electrode GEN of the n channel MOS transistor Qn, oxygen in bonded to the alloy containing ruthenium as a base material and hafnium (Hf—Ru). In addition, the gate insulating film GI is made of hafnium oxide in both the p channel MOS transistor Qp and the n channel MOS transistor Qn. However, the amount of oxygen is smaller in the gate insulating film GI of the n channel MOS transistor Qn than in the gate insulating film GI of the p channel MOS transistor Qp (oxygen deficiency), and thus the dipole is generated. For these reasons, it is thought that the effective work function of the gate electrode GEN after the oxygen-deficient annealing becomes lower than the effective work function of the gate electrode GEP.

Generally, a high-k material to be used for a gate insulating film is the oxide which satisfies a stoichiometric composition ratio. In the first embodiment, however, the hafnium oxide which forms the gate insulating film GI of the p channel MOS transistor Qp is densified by performing the oxygen-deficient annealing, and the hafnium oxide which forms the gate insulating film GI of the n channel MOS transistor Qn is configured so as to be deficient in oxygen while maintaining the densification. In other words, the gate insulating film GI of the n channel MOS transistor Qn is configured to have the oxygen concentration lower than the oxygen concentration in the gate insulating film GI of the p channel MOS transistor Qp.

In addition, it has been confirmed that, when the oxygen-deficient annealing is performed in the oxygen atmosphere without providing the cap layer CL formed on the gate electrode GEN, the shift amount of the work function of the gate electrode GEN is reduced in comparison to the case where the cap layer CL is provided. This is because, since hafnium of the Hf—Ru layer is oxygen-bonded to oxygen of the HfO₂ layer below the Hf—Ru layer and oxygen above the Hf—Ru layer (in the atmosphere), the amount of oxygen deficiency of the HfO₂ layer is reduced.

In the first embodiment, the difference in work function (shift amount) between the gate electrode GEP of the p MOS transistor and the gate electrode GEN of the n MOS transistor can be increased by providing the cap layer CL made of tantalum nitride. When the cap layer CL is provided on the gate electrode GEN, hafnium of the gate electrode GEN formed of an Hf—Ru layer is oxygen-bonded to oxygen released from the HfO₂ layer even if the oxygen-deficient annealing is performed in the oxidation atmosphere, not to mention the case where the oxygen-deficient annealing is performed in the non-oxidation atmosphere.

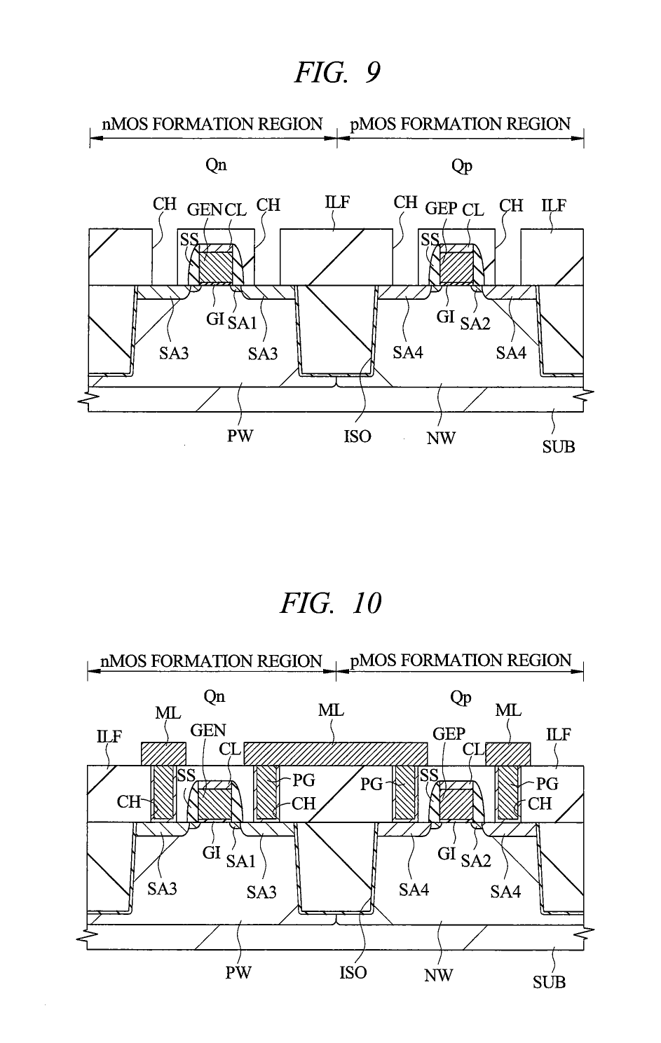

Subsequently, as shown in FIG. 9, an interlayer insulating film ILF made of silicon oxide is formed on the substrate SUB by CVD, and the surface thereof is planarized by chemical mechanical polishing. Thereafter, the interlayer insulating film ILF is dry-etched using a photoresist film as a mask, thereby forming contact holes CH above the n⁺ semiconductor regions (source, drain) SA3 and the p⁺ semiconductor regions (sources drain) SA4.

Then, as shown in FIG. 10, plugs PG are formed in the contact holes CH, and metal wirings ML are formed on the interlayer insulating film ILF. The plugs PG are formed by depositing a titanium nitride (TiN) film and a tungsten (W) film by sputtering on the interlayer insulating film ILF including an interior of the contact holes CH and then removing the TiN film and the W film on the interlayer insulating film ILF by the chemical mechanical polishing. Also, the metal wirings ML are formed by depositing a metal film such as a W film or an Al alloy film by sputtering on the interlayer insulating film ILF and then patterning the metal film by the dry etching using a photoresist film (not shown) as a mask.

Through the process described above, the CMOS in which the work function of the gate electrode GEN of the n channel MOS transistor Qn is lower than the work function of the gate electrode GEP of the p channel MOS transistor Qp is completed.

As described above, in the first embodiment, the gate insulating film GI made of hafnium-based oxide is first formed on the main surface of the substrate SUB having the p MOS formation region in which the p channel MOS transistor Qp is formed and the nMOS formation region in which the n channel MOS transistor Qn is formed. Subsequently, the metal film MF1 made of ruthenium (Ru) is formed on the gate insulating film GI. Then, after the metal film MF1 of the nMOS formation region is removed to expose the gate insulating film GI, the metal film MF2 made of alloy (Hf—Ru) containing ruthenium as a base material and hafnium is formed on the gate insulating film GI of the nMOS formation region. Thereafter, the oxygen-deficient annealing is performed to the substrate SUB so that oxygen is lost from the gate insulating film GI of the nMOS formation region. In this manner, the gate electrode GEN of the n channel MOS transistor Qn whose work function is lower than that of the gate electrode GEP of the p channel MOS transistor Qp can be formed.

According to the first embodiment, two types of the gate electrodes GEN and GEP each having different work functions can be formed in fewer manufacturing processes than the case where two types of metal materials each having different work functions are used.

### Second Embodiment

Although the configuration in which the gate electrode of the n channel MOS transistor is formed of an alloy film containing ruthenium as a base material and hafnium has been described in the first embodiment, the case of a stacked structure in which a hafnium film is deposited on a ruthenium film will be described in the second embodiment.

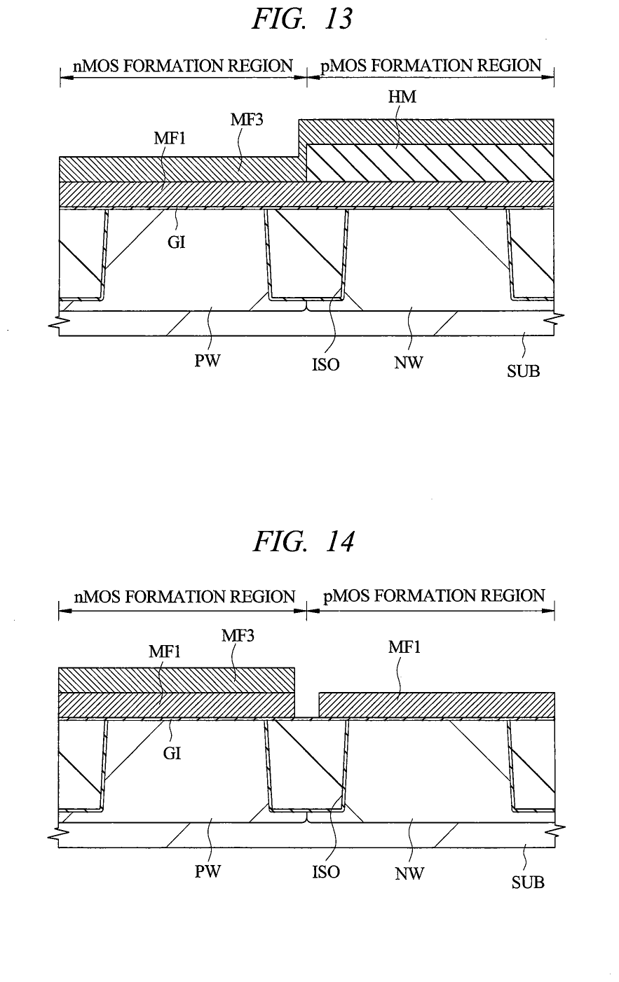

The manufacturing method of a CMOS constituted of an n channel MOS transistor and a p channel MOS transistor according to the second embodiment will be described with reference to FIG. 13 to FIG. 15. Note that FIG. 13 is a cross-sectional view showing a principal part of a semiconductor device in the manufacturing process continued from the process described with reference to FIG. 2 in the first embodiment.

As shown in FIG. 13, the metal film MF1 made of ruthenium is deposited (formed) on the gate insulating film GI made of hafnium-based oxide (hafnium oxide in the second embodiment) by sputtering, and a silicon nitride film is deposited on the metal film MF1 by CVD. Thereafter, the silicon nitride film is patterned by the dry etching using a photoresist film (not shown) as a mask, thereby forming the hard mask HM in the pMOS formation region. In the second embodiment, the thickness of the metal film MF1 made of ruthenium is, for example, 10 nm.

Subsequently, a metal film MF3 made of hafnium is deposited (formed) on the metal film MF1 in the nMOS formation region by sputtering, and a silicon nitride film is deposited on the metal film MF3 by CVD. Thereafter, the silicon nitride film is patterned by the dry etching using a photoresist film (not shown) as a mask, thereby forming a hard mask (not shown) in the nMOS formation region. In the second embodiment, the thickness of the metal film MF3 made of hafnium is, for example, 10 nm.

Then, unnecessary portions of the metal film MF3 and the metal film MF1 are removed by the etching using the hard mask of the nMOS formation region and the hard mask HM of the p MOS formation region. Thereafter, as shown in FIG. 14, the hard mask HM of the pMOS formation region and the hard mask of the nMOS formation region are removed.

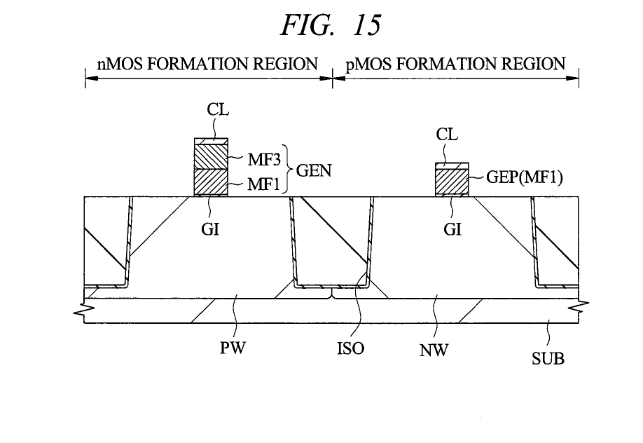

Subsequently, as shown in FIG. 15, the cap layer CL made of tantalum nitride (barrier metal) is deposited (formed) on the metal film MF1 of the pMOS formation region and the metal film MF3 of the nMOS formation region. Thereafter, the cap layer CL and the metal films MF1 and MF3 are patterned by the dry etching using a photoresist film (not shown) as a mask. By this means, the gate electrode GEP formed of the metal film MF1 and the gate electrode GEN formed of a stacked film of the metal film MF1 and the metal film MF3 are formed on the gate insulating film GI of the n well NW and the gate insulating film GI of the p well PW, respectively.

Thereafter, through the process similar to that described with reference to FIG. 7 to FIG. 10 in the first embodiment (including oxygen-deficient annealing), the CMOS constituted of a p channel MOS transistor and an n channel MOS transistor is completed.

When the effective work function of the gate electrodes GEP and GEN is measured, the effective work function of the gate electrode GEN is lower than that of the gate electrode GEP. In the second embodiment, the metal film MF3 is stacked on the metal film MF1 with the thickness of 10 nm in the formation of the gate electrode GEN. In this case, the effective work function of the gate electrode GEN is 4.5 eV, and the effective work function of the gate electrode GEP made of ruthenium is 5.0 eV.

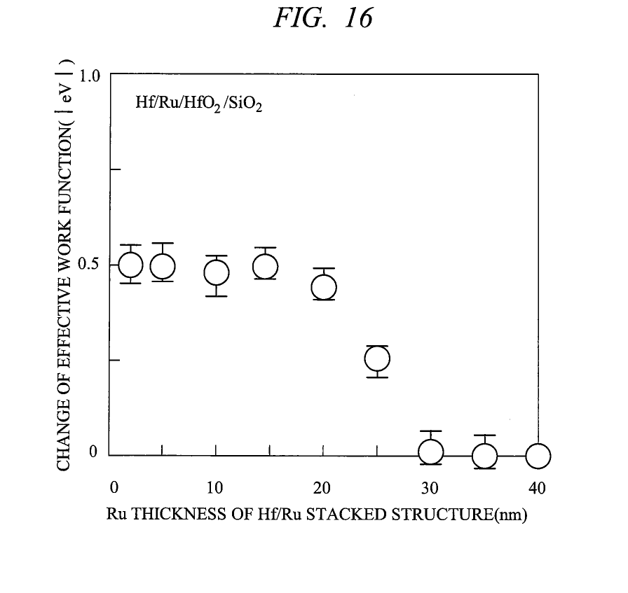

FIG. 16 shows the change of the effective work function relative to the thickness of the ruthenium (Ru) film (metal film MF1) of the n channel MOS transistor Qn with respect to the p channel MOS transistor Qp. As shown in FIG. 16, by forming the Ru film to have the thickness of 15 nm or less, the difference in the effective work function can be reduced to 0.5 eV. However, the difference in the effective work function decreases as the thickness of the Ru film is increased to more than 15 nm, and the difference in the work function disappears when the thickness reaches 30 nm or more.

From the description above, it can be said that the gate electrode GEN formed of a stacked film of the ruthenium film (metal film MF1) and the hafnium film (metal film MF3) shifts the work function relative to the ruthenium film (metal film MF1) forming the gate electrode GEP if the thickness of the metal film MF1 is smaller than 30 nm. Note that, when the thickness of the metal film MF1 made of ruthenium is 0 nm (when the metal film MF3 made of hafnium is directly formed on the gate insulating film GI), the gate insulating film GI is in a conduction state, and the effective work function cannot be measured.

The reason why the work function of the gate electrode GEN is lower than that of the gate electrode GEP will be described below. First, by performing the oxygen-deficient annealing, hafnium of the metal film MF3 is bonded to oxygen released from hafnium oxide of the gate insulating film GI. This is because the gate electrode GEN is formed of a stacked film of the metal film MF1 with the thickness through which oxygen can pass and the metal film MF3 made of metal (hafnium in the second embodiment) which is more oxidation stable than hafnium oxide. Therefore, the metal film MF3 made of hafnium contained in the gate electrode GEN is bonded to oxygen.

Subsequently, since oxygen has been taken out, the HfO₂ layer is deficient in oxygen. Then, electrons are accumulated in the HfO₂ layer due to the oxygen deficiency, and dipole is generated at the interface of the HfO₂ layer and the SiO₂ layer. It is thought that the effective work function of the gate electrode GEN after the oxygen-deficient annealing becomes lower than the effective work function of the gate electrode GEP with such a mechanism.

As described above, in the second embodiment, the gate insulating film GI made of hafnium-based oxide is formed on the main surface of the substrate SUB having the p MOS formation region in which the p channel MOS transistor Qp is formed and the nMOS formation region in which the n channel MOS transistor Qn is formed. Subsequently, the metal film MF1 made of ruthenium (Ru) is formed on the gate insulating film GI. Then, the metal film MF3 made of ruthenium is formed on the metal film MF1 of the nMOS formation region. Thereafter, the oxygen-deficient annealing is performed to the substrate SUB so that oxygen is lost from the gate insulating film GI of the nMOS formation region. In this manner, the gate electrode GEN of the n channel MOS transistor Qn whose work function is lower than that of the gate electrode GEP of the p channel MOS transistor Qp can be formed.

According to the second embodiment, two types of the gate electrodes GEN and GEP each having different work functions can be formed in fewer manufacturing processes than the case where two types of metal materials each having different work functions are used.

### Third Embodiment

Although the case where hafnium-based oxide is applied to the gate insulating film of the p channel MOS transistor and the gate insulating film of the n channel MOS transistor has been described in the first and second embodiments, the case where aluminum oxide (Al₂O₃) is applied thereto will be described in the third embodiment.

The manufacturing method of a CMOS constituted of an n channel MOS transistor and a p channel MOS transistor according to the third embodiment differs in that aluminum oxide (Al₂O₃) is used to form the gate insulating film GI in the process described with reference to FIG. 2 after the process described with reference to FIG. 1 in the first embodiment.

Aluminum oxide is deposited by, for example, the ALD using an O (oxygen) material of H₂O and TMA (Trimethylaluminum: AlMe₃) of an Al (aluminum) material. Thereafter, PDA is performed thereto in order to reduce the defects in the film.

This aluminum oxide is the oxide whose relative dielectric constant is higher than that of silicon oxide (SiO₂). The relative dielectric constant of the gate insulating film GI made of aluminum oxide is about 8, and if the thickness is set to, for example, 2.4 nm, the equivalent oxide thickness (EOT) is, for example, 1.2 nm. In this case, the leakage current when the MOS transistor is in an ON state can be reduced in comparison to a MOS transistor having a gate insulating film formed of a silicon oxide film with the same thickness.

Thereafter, through the process similar to that described with reference to FIG. 3 to FIG. 10 in the first embodiment (including oxygen-deficient annealing), the CMOS constituted of a p channel MOS transistor and an n channel MOS transistor is completed.

When the effective work function of the gate electrodes GEP and GEN is measured, the effective work function of the gate electrode GEN is lower than that of the gate electrode GEP. In the third embodiment, ruthenium is used as a base material and 10 atom % of hafnium is added in the formation of the gate electrode GEN. In this case, the effective work function of the gate electrode GEN is 4.8 eV, and the effective work function of the gate electrode GEP made of ruthenium is 5.5 eV.

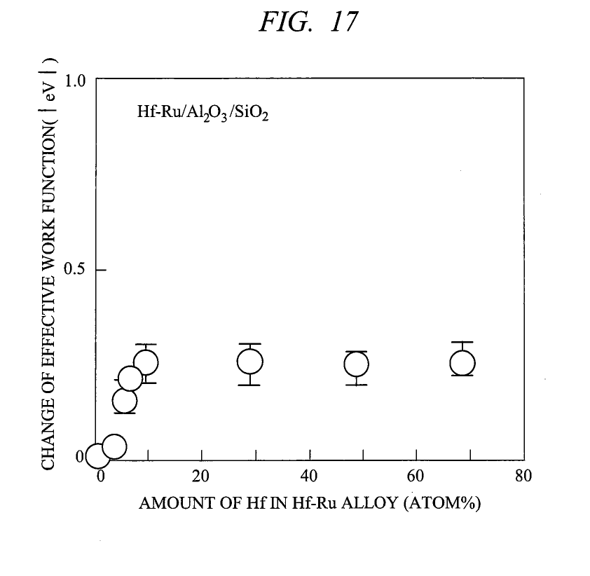

FIG. 17 shows the change of the effective work function relative to the hafnium (Hf) content of the n channel MOS transistor Qn with respect to the p channel MOS transistor Qp. As shown in FIG. 17, by increasing the Hf content, the difference in the effective work function between the p channel MOS transistor Qp and the n channel MOS transistor Qn increases, and the difference reaches 0.25 eV when the Hf content is 10 atom %. In addition, the difference in the effective work function saturates when the Hf content is increased to more than 10 atom %.

From the description above, it can be said that the alloy containing ruthenium as a base material and hafnium for forming the gate electrode GEN shifts the work function as a gate electrode material relative to ruthenium for forming the gate electrode GEP even when aluminum oxide is used for the gate insulating film GI. According to the third embodiment, two types of the gate electrodes GEN and GEP each having different work functions can be formed in fewer manufacturing processes than the case where two types of metal materials each having different work functions are used.

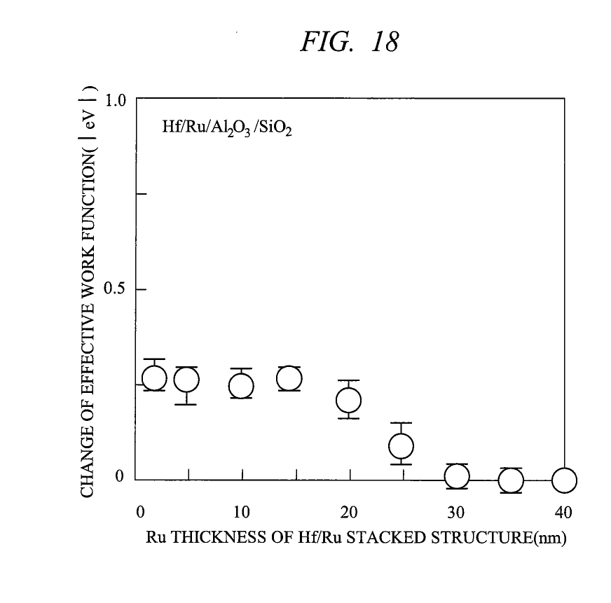

Also, the case where the gate electrode GEN of the n channel MOS transistor Qn has a stacked structure in which a hafnium film is deposited on a ruthenium film as described in the second embodiment will be described. FIG. 18 shows the change of the effective work function relative to the thickness of the ruthenium (Ru) film (metal film MF1) of the n channel MOS transistor Qn with respect to the p channel MOS transistor Qp. As shown in FIG. 18, by forming the Ru film to have the thickness of 15 nm or less, the difference in the effective work function can be reduced to 0.25 eV. However, the difference in the effective work function decreases as the thickness of the Ru film is increased to more than 15 nm, and the difference in the work function disappears when the thickness reaches 30 nm or more.

As described above, even when the gate electrode GEN of the n channel MOS transistor Qn is formed to have the stacked structure in which a hafnium film is stacked on a ruthenium film, two types of the gate electrodes GEN and GEP each having different work functions can be formed in fewer manufacturing processes than the case where two types of metal materials each having different work functions are used.

### Fourth Embodiment

Although the case where ruthenium is applied as a base material of a gate electrode of a p channel MOS transistor and a gate electrode of an n channel MOS transistor has been described in the, first to third embodiments, the case where any one of ruthenium, platinum, rhenium, iridium, nickel, palladium, cobalt and gold or the combination thereof is applied will be described in the fourth embodiment.

Also, although the case where hafnium is applied as an additive element to a base material of the gate electrode of the n channel MOS transistor has been described in the first embodiment, the case where any one of hafnium, titanium, zirconium, scandium, yttrium, tantalum, aluminum, magnesium, calcium, strontium, barium, and a rare-earth element or the combination thereof is applied will be described in the fourth embodiment.

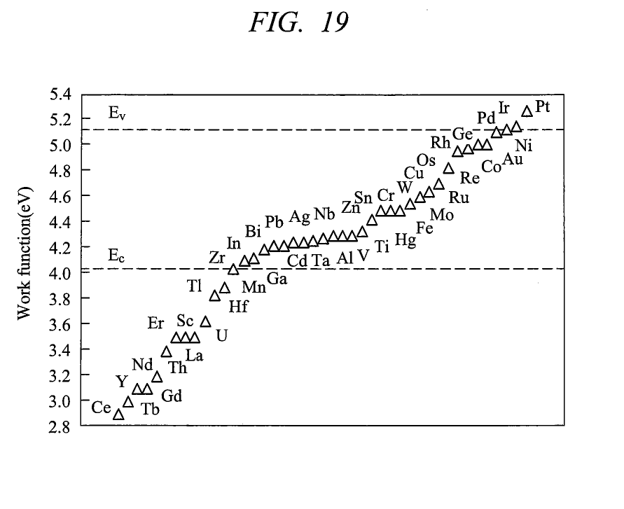

FIG. 19 is a drawing for describing the work function of various elements. In FIG. 19, lines are shown near 5.1 eV generally required as the work function (Ev) of a gate electrode material of the p channel MOS transistor and near 4.1 eV generally required as the work function (Ec) of a gate electrode material of the n channel MOS transistor.

As shown in FIG. 19, the work function of ruthenium (Ru) is about 4.7 eV and is close to the work function (Ev). Therefore, ruthenium is applied to the gate electrode GEP of the p channel MOS transistor in the first to third embodiments.

Also, the work function of hafnium (Hf) is about 3.9 eV and is lower than the work function (Ec). The metal element with lower work function has larger electron affinity and easily reacts with oxygen, in other words, easily becomes oxidation stable. Therefore, in the first to third embodiments described above, alloy containing ruthenium on a side of the work function (Ev) as a base material and hafnium which is more oxidation stable than the hafnium-based oxide or aluminum oxide forming the gate insulating film GI is applied as the gate electrode GEN of the n channel MOS transistor.

As described above, any metal can be applied as the gate electrode GEP of the p channel MOS transistor Qp as long as it can constitute alloy with an element having low work function and is close to the work function (Ev), and any one of ruthenium, platinum, rhenium, iridium, nickel, palladium, cobalt, and gold or the combination thereof can be applied.

In addition, any alloy can be applied as the gate electrode GEN of the n channel MOS transistor Qn as long as it contains any one of ruthenium, platinum, rhenium, iridium, nickel, palladium, cobalt, and gold or the combination thereof as a base material and metal which has low work function and is more oxidation stable than hafnium-based oxide or aluminum oxide forming the gate insulating film GI. For example, any one of hafnium, titanium, zirconium, scandium, yttrium, tantalum, aluminum, magnesium, calcium, strontium, barium, and a rare-earth element or the combination thereof can be applied.

Note that the rare earth element mentioned here includes 17 elements such as scandium (Sc), yttrium (Y), lanthanum (La), cerium (Ce), praseodymium (Pr), neodymium (Nd), promethium (Pm), samarium (Sm), europium (Eu), gadolinium (Gd), terbium (Tb), dysprosium (Dy), holmium (Ho), erbium (Er), thulium (Tm), ytterbium (Yb), and lutetium (Lu). Any one of these rare-earth elements or the combination thereof can be applied as the additive element.

Even in the case of using such materials, two types of the gate electrodes GEN and GEP each having different work functions can be formed in fewer manufacturing processes than the case where two types of metal materials each having different work functions are used.

### Fifth Embodiment

Although the case where a gate electrode of an n channel MOS transistor is made of alloy (Hf—Ru) containing ruthenium formed by sputtering as a base material and hafnium has been described in the first embodiment, the case where the gate electrode is made of alloy (Hf—Ru) obtained by introducing hafnium into a ruthenium film by ion implantation will be described in the fifth embodiment.

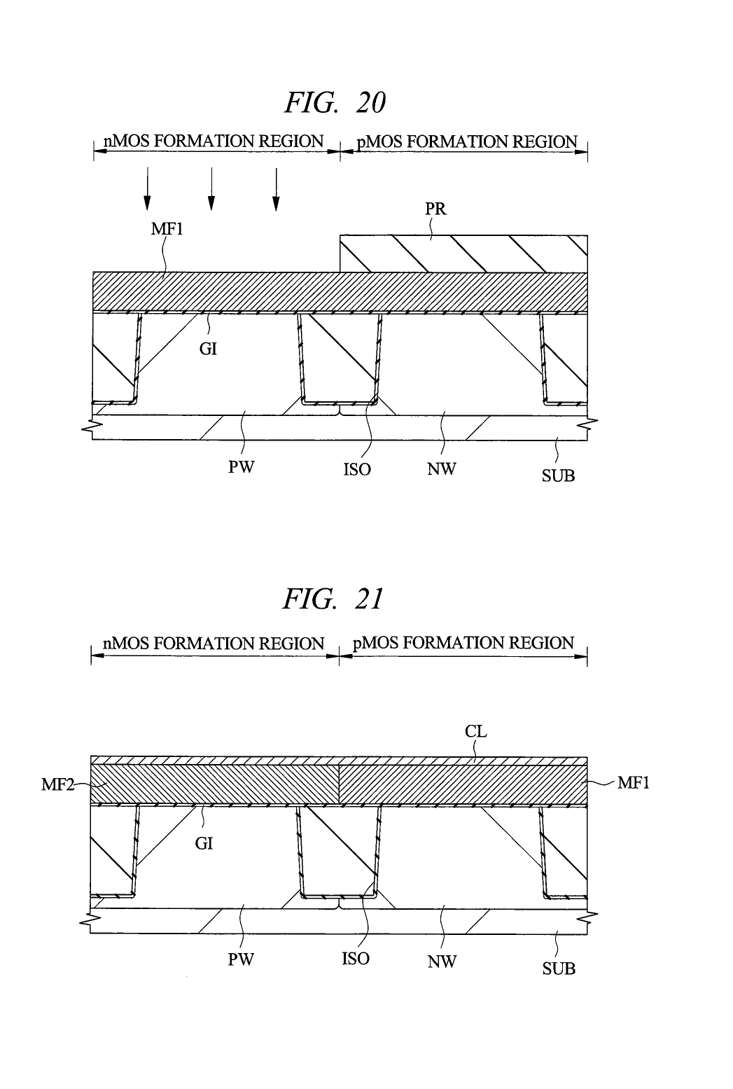

The manufacturing method of a CMOS constituted of an n channel MOS transistor and a p channel MOS transistor according to the fifth embodiment will be described with reference to FIG. 20 and FIG. 21. Note that FIG. 20 is a cross-sectional view showing a principal part of a semiconductor device in the manufacturing process continued from the process described with reference to FIG. 2 in the first embodiment.

As shown in FIG. 20, after depositing a ruthenium film (metal film MF1) by sputtering on the gate insulating film GI, a photoresist film RP is formed in the pMOS formation region through the photolithography and etching processes. Then, hafnium is introduced into a ruthenium film in the nMOS formation region with a dose amount of 5×10¹⁵ cm⁻² by ion implantation.

Subsequently, as shown in FIG. 21, after the photoresist film PR is removed, the heat treatment for homogenizing the hafnium in the ruthenium film of the nMOS formation region is performed. By this means, the metal film MF2 made of alloy (Hf—Ru) is formed in the nMOS formation region. Subsequently, the cap layer CL made of tantalum nitride (barrier metal) is deposited (formed) on the metal film MF1 of the pMOS formation region and a metal film MF4 of the nMOS formation region.

Then, the gate electrode GEN formed of the metal film MF2 and the gate electrode GEP formed of the metal film MP1 are patterned and formed by collectively etching the nMOS formation region and the pMOS formation region in the same manner as shown in FIG. 6. Thereafter, through the process similar to that described with reference to FIG. 7 to FIG. 10 in the first embodiment (including oxygen-deficient annealing), the CMOS constituted of a p channel MOS transistor and an n channel MOS transistor is completed.

As an advantage of this method, it is possible to omit the process of removing the metal film MF1 of the nMOS formation region by etching to expose the gate insulating film GI of the nMOS formation region, and then depositing (forming) the metal film MF2 made of alloy (Hf—Ru) containing ruthenium as a base material and hafnium on the gate insulating film GI by sputtering as described in the first embodiment.

### Sixth Embodiment

Although the case where a gate insulating film and gate electrodes are first formed and then source and drain are formed (gate-first process) has been described in the first embodiment, the case where a gate insulating film and gate electrodes are formed after forming source and drain (gate-last process) will be described in the sixth embodiment.

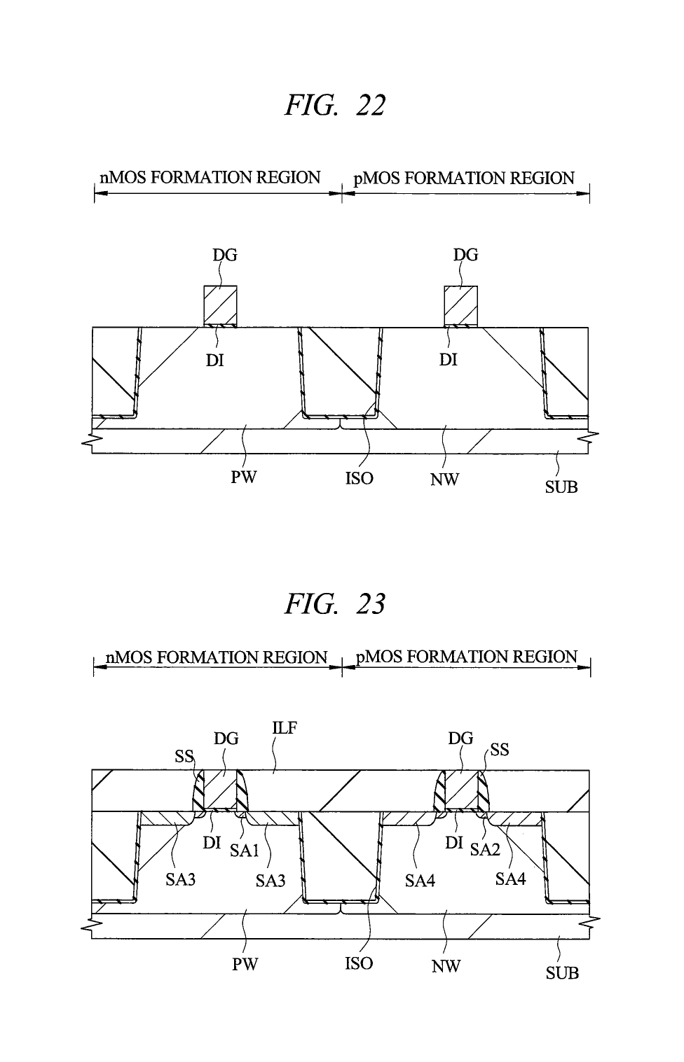

The manufacturing method of a CMOS constituted of an n channel MOS transistor and a p channel MOS transistor according to the sixth embodiment will be described with reference to FIG. 22 to FIG. 27. Note that FIG. 22 is a cross-sectional view showing a principal part of a semiconductor device in the manufacturing process continued from the process described with reference to FIG. 1 in the first embodiment.

As shown in FIG. 22, after an insulating film DI made of silicon oxide is formed on the surfaces of the p well PW and the n well NW by the thermal oxidation of the substrate SUB, a polysilicon film is deposited on the substrate SUB by the CVD. Thereafter, the polysilicon film is patterned by the dry etching using a photoresist film as a mask, thereby forming dummy gate electrodes DG on each of the insulating films DI of the p well PW and the n well NW. Note that the material of the dummy gate electrode DG is not limited to a polysilicon film, and it is also possible to use various insulating materials and metal materials having a high etching selectivity to a silicon-oxide-based insulating film such as an amorphous silicon film.

Subsequently, as shown in FIG. 23, through the process described with reference to FIG. 7 and FIG. 8 in the first embodiment, the n⁻ semiconductor regions SA1, the p⁻ semiconductor regions SA2, the sidewall spacers SS, the n⁺ semiconductor regions (source, drain) SA3 and the p⁺ semiconductor regions (source, drain) SA4 are sequentially formed. Thereafter, the surface of the interlayer insulating film ILF deposited on the substrate SUB is polished and planarized by the chemical mechanical polishing, thereby exposing the surfaces of the dummy gate electrodes DG on the surface of the interlayer insulating film ILF.

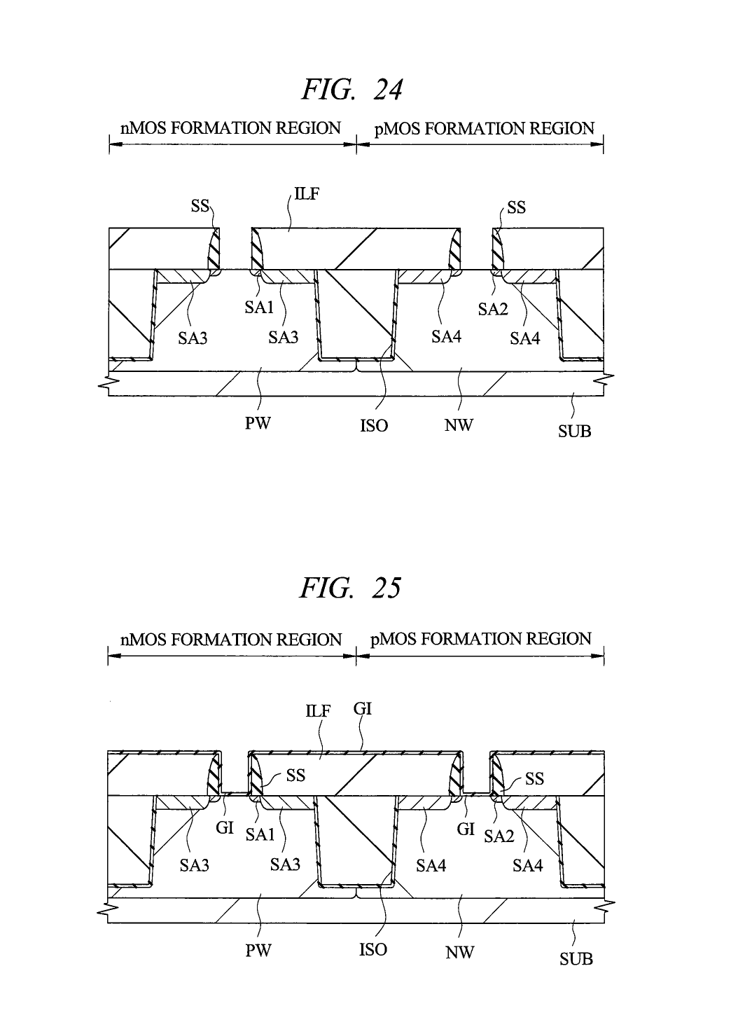

Then, as shown in FIG. 24, after removing the dummy gate electrodes DG by etching, the insulating films DI in the regions exposed by the removal of the dummy gate electrodes DG are removed by etching.

Subsequently, as shown in FIG. 25, on the inner walls of the concave trenches formed by the removal of the dummy gate electrodes DG and on the surface of the substrate SUB (p well PW, n well NW) exposed by the removal of the insulating film DI, an interface layer made of silicon oxide is formed and the gate insulating film GI made of hafnium oxide (HfO₂) is formed thereon in the same manner as that described with reference to FIG. 2 in the first embodiment. Note that the gate insulating film GI is deposited to have a small thickness so as not to fill the concave trenches formed by the removal of the dummy gate electrodes DG.

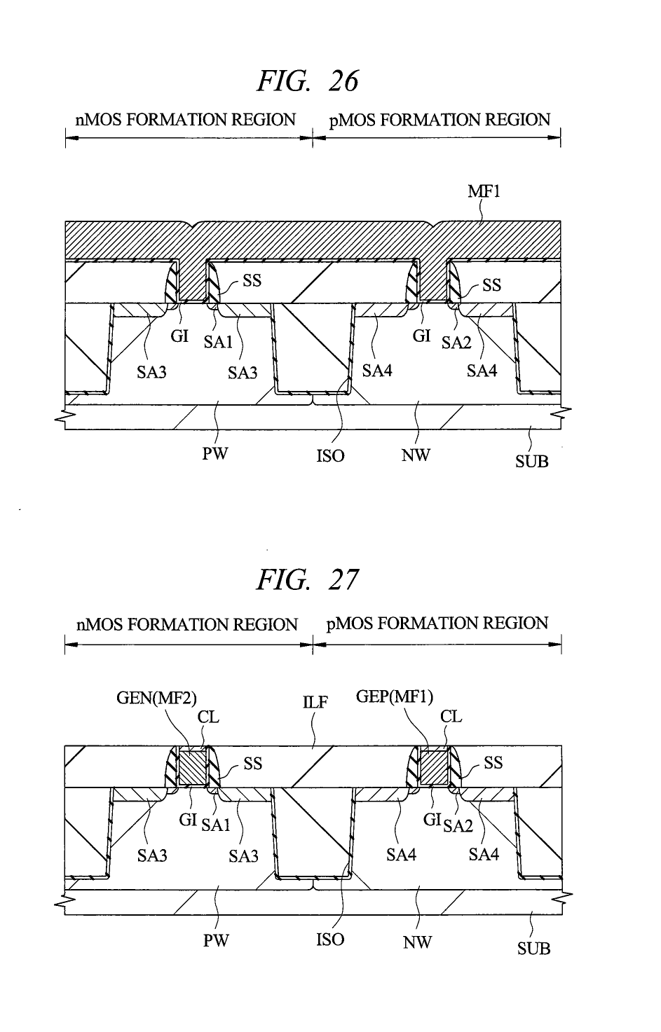

Then, as shown in FIG. 26, the metal film MF1 made of ruthenium is deposited on the gate insulating film GI by CVD, thereby filling the concave trenches with the metal film MF1.

Subsequently, the metal film MF2 made of alloy (Hf—Ru) is formed in the nMOS formation region through the process described with reference to FIG. 20 in the fifth embodiment. Then, the metal films MF1 and MF2 filled in the concave trenches are partially removed by etching, and the cap layer CL formed of a tantalum nitride film is deposited on the surface of the substrate SUB. Thereafter, the tantalum nitride film and the insulating film DI outside the concave trenches are removed by the chemical mechanical polishing.

Then, through the process similar to that described with reference to FIG. 21 in the fifth embodiment, the substrate SUB is annealed at 400° C. so that oxygen is lost from the gate insulating film GI made of oxide in the nMOS formation region (oxygen-deficient annealing). Thereafter, through the process similar to that described with reference to FIG. 9 and FIG. 10 in the first embodiment, the CMOS constituted of a p channel MOS transistor and an n channel MOS transistor is completed.

Since the gate insulating film GI formed of a high dielectric film and the gate electrodes GEN and GEP formed of a metal film are formed after finishing the heat treatment to diffuse the source and drain, the oxygen-deficient annealing can be performed at a low temperature of 400° C. By this means, it is possible to prevent the decrease in mobility due to the reaction between the high dielectric film forming the gate insulating film GI and the metal film forming the gate electrodes GEN and GEP by the heat treatment in the formation of the source and drain.

In the foregoing, the invention made by the inventors of the present invention has been concretely described based on the embodiments. However, it is needless to say that the present invention is not limited to the foregoing embodiments and various modifications and alterations can be made within the scope of the present invention.

For example, in the embodiments above, hafnium-based oxide (Hf—O) and aluminum oxide (Al₂O₃) have been shown as the material of a gate insulating film. However, the gate insulating film made of tantalum oxide (Ta₂O₅), titanium oxide (TiO₂), lanthanum oxide (La₂O₃) or zirconium oxide (ZrO₂) is also available. The bonding to oxygen of tantalum oxide, titanium oxide, lanthanum oxide and zirconium oxide is weaker than that of aluminum oxide (Al₂O₃) described in the embodiments above, and the bonding to oxygen thereof is equal to or stronger than that of hafnium-based oxide such as hafnium oxide (HfO₂). Thus, by using the alloy containing metal which is more oxidation stable than tantalum oxide, titanium oxide, lanthanum oxide and zirconium oxide (oxides) to form the gate electrode, the oxygen deficiency occurs in the oxide to generate the dipole, and the work function is decreased.

The present invention can be widely utilized for the manufacture of a semiconductor device, in particular, a semiconductor device comprising MOS transistors having a gate insulating film made of a material whose relative dielectric constant is higher than that of silicon oxide (SiO₂) and a gate electrode made of a metal material.

What is claimed is:

1. A semiconductor device, comprising:
a p channel MOS transistor formed in a first region of a main surface of a semiconductor substrate and having a first gate electrode; and
an n channel MOS transistor formed in a second region of the main surface and having a second gate electrode whose work function is lower than that of the first gate electrode,
wherein gate insulating films of the p channel MOS transistor and the n channel MOS transistor are made of oxide whose relative dielectric constant is higher than that of silicon oxide,
the first gate electrode is made of first metal, and
the second gate electrode is made of alloy containing second metal which is the same as the first metal as a base material and third metal which is more oxidation stable than the oxide.

2. The semiconductor device according to claim 1,
wherein the first metal and the second metal are any one of ruthenium, platinum, rhenium, iridium, nickel, palladium, cobalt, and gold or combination thereof.

3. The semiconductor device according to claim 1,
wherein the third metal is any one of hafnium, titanium, zirconium, scandium, yttrium, tantalum, aluminum, magnesium, calcium, strontium and barium or a rare-earth element.

4. The semiconductor device according to claim 1,
wherein the oxide is hafnium-based oxide.

5. The semiconductor device according to claim 1,
wherein the oxide is aluminum oxide.

6. The semiconductor device according to claim 1,
wherein the second gate electrode is formed by stacking the second metal and the third metal in this order from a side of the gate insulating film.

7. The semiconductor device according to claim 1,
wherein the third metal contained in the second gate electrode is bonded to oxygen.

8. The semiconductor device according to claim 1,
wherein an amount of oxygen in the gate insulating film of the n channel MOS transistor is smaller than an amount of oxygen in the gate insulating film of the p channel MOS transistor.

9. The semiconductor device according to claim 1,
wherein the second gate electrode is made of alloy containing the second metal which is the same as the first metal as a base material and the third metal which is more oxidation stable than the oxide and is introduced by ion implantation.

10. A manufacturing method of a semiconductor device, comprising the steps of:
(a) forming a gate insulating film made of hafnium-based oxide or aluminum oxide on a main surface of a semiconductor substrate having a first region in which a p channel MOS transistor is formed and a second region in which an n channel MOS transistor is formed;
(b) forming a first film made of any one of ruthenium, platinum, rhenium, iridium, nickel, palladium, cobalt, and gold or combination thereof on the gate insulating film;
(c) removing the first film in the second region, thereby exposing the gate insulating film in the second region;
(d) after the step (c), forming a second film made of alloy containing any one of ruthenium, platinum, rhenium, iridium, nickel, palladium, cobalt, and golden or combination thereof as a base material and hafnium, titanium, zirconium, scandium, yttrium, tantalum, aluminum, magnesium, calcium, strontium, barium or a rare-earth element on the gate insulating film in the second region; and
(e) after the step (d), annealing the semiconductor substrate so that oxygen is lost from the gate insulating film in comparison to a state just after the step (a).

11. The manufacturing method of a semiconductor device according to claim 10, further comprising the step of:
(f) between the steps (d) and (e), forming a cap layer made of barrier metal on the first film in the first region and on the second film in the second region.

12. The manufacturing method of a semiconductor device according to claim 10,
wherein, in the step (e), the semiconductor substrate is annealed so that oxygen lost from the gate insulating film is bonded to the hafnium, titanium, zirconium, scandium, yttrium, tantalum, aluminum, magnesium, calcium, strontium, barium or the rare-earth element.

13. A manufacturing method of a semiconductor device, comprising the steps of:
(a) forming a gate insulating film made of hafnium-based oxide or aluminum oxide on a first region of a semiconductor substrate in which a p channel MOS transistor is formed and a second region of the semiconductor substrate in which an n channel MOS transistor is formed;
(b) forming a first film made of any one of ruthenium, platinum, rhenium, iridium, nickel, palladium, cobalt, and gold or combination thereof on the gate insulating film;
(c) forming a second film made of hafnium, titanium, zirconium, scandium, yttrium, tantalum, aluminum, magnesium, calcium, strontium, barium or a rare-earth element on the first film in the second region; and
(d) after the step (c), annealing the semiconductor substrate so that oxygen is lost from the gate insulating film in comparison to a state just after the step (a).

14. The manufacturing method of a semiconductor device according to claim 13, further comprising the step of:
(e) between the steps (c) and (d), forming a cap layer made of barrier metal on the first film in the first region and on the second film in the second region.

15. The manufacturing method of a semiconductor device according to claim 13,
wherein, in the step (d), the semiconductor substrate is annealed so that oxygen lost from the gate insulating film is bonded to the hafnium, titanium, zirconium, scandium, yttrium, tantalum, aluminum, magnesium, calcium, strontium, barium or the rare-earth element.
